(19) United States
(12) Patent Application Publication
(10) Pub. No.: US 2008/0006915 A1
(43) Pub. Date: Jan. 10, 2008

(54) Semiconductor package, method of production of same, printed circuit board, and electronic apparatus

(75) Inventors: Naoaki Nakamura, Kawasaki (JP); Hideaki Yoshimura, Kawasaki (JP); Kenji Fukuzono, Kawasaki (JP); Toshihisa Sato, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/641,718

(22) Filed: Dec. 20, 2006

(30) Foreign Application Priority Data
Jul. 6, 2006 (JP) 2006-186596

(51) Int. Cl. H01L 23/495

(52) U.S. Cl. 257/675

(57) ABSTRACT

A semiconductor package provided with a heat radiator achieving a further improvement of reliability by reducing an influence of thermal stress. For this purpose, the heat radiator is formed by a heat radiator comprised of a heat radiation plate plus a box shaped part and comprised so that the entire semiconductor chip is enclosed in this box shaped part together with a board via a metallic bonding material.

### BACKGROUND OF THE INVENTION

1. Field of the Invention

The present invention relates to a semiconductor package, more particularly relates to a semiconductor package provided with an LSI or other semiconductor chip, a printed circuit board supporting this semiconductor chip at its bottom surface (hereinafter referred to as a “board”), and a heat spreader, heat sink, or other heat radiator provided on a back surface of the semiconductor chip. Further, it relates to a method of production of a semiconductor package, a printed circuit board, and an electronic apparatus.

2. Description of the Related Art

In recent years, to increase the density of mounting of semiconductor chips, mounting is changing to so-called flip chip mounting bonding a bare chip itself onto the board. This enables a further reduction of size and improvement of function of an information apparatus. On the other hand, the higher density of circuit elements accompanying the smaller size and the faster speed of circuit operation accompanying the higher functions tend to result in remarkably increased generation of heat from the semiconductor chip.

For this reason, the cooling technique for cooling a semiconductor chip with a high efficiency is becoming important. The key element of this cooling technique is the heat spreader, heat sink, or heat radiator explained before. When this heat radiator is provided on the back surface of an LSI etc., the general practice is to coat silicone grease or insert a heat radiation sheet between the back surface and the heat radiator.

However, with the technique of using silicone grease or a heat radiation sheet to conduct heat generated from the semiconductor chip to the outside, the heat resistance becomes significant along with an increase of the heat generation. There is therefore a limit to the heat radiation capability.

Therefore, in recent years, as a technique able to greatly reduce the above heat resistance, the use of a metallic bonding material in place of silicone grease etc. described above has been proposed and has begun to be widely put into practical use. A preferred example of this metallic bonding material is solder. That is, a heat radiator made of for example copper is directly soldered onto the back surface of a presoldered semiconductor chip. The heat generated from the semiconductor chip is therefore absorbed by the heat radiator with an extremely high efficiency and diffused to the outside.

However, on the other hand, the semiconductor chip itself or the boundary portion between the semiconductor chip and the heat radiator easily breaks. The problem arises that the cooling performance of the semiconductor chip is improved, but the semiconductor chip is remarkably lowered in reliability.

Note that, as known art related to the present invention, there are the following Japanese Patent Publication No. 2002-158316 and Japanese Patent Publication No. 2002-203866. These patent publications disclose structures appearing to be similar to the structure of the heat radiator inherent to the present invention explained later. However, when studying these in detail, the structures of the heat radiators disclosed in these patent publications are basically very different from the present invention. This is because the technical ideas concerning the design of the heat radiator are basically different.

The breakage explained before at the back surface portion of the semiconductor chip or the boundary portion between the semiconductor chip and the heat radiator is considered to be due to the generation of excessive thermal stress due to the difference in heat expansion in these portions due to the improvement of heat propagation by using the above metallic bonding material. In the end, the cooling capability is greatly improved, but excessive thermal stress is generated, so breakage occurs in the above-described portions and the reliability of the semiconductor package is lowered. This is the problem.

### SUMMARY OF THE INVENTION

Accordingly, in consideration with the above problems, an object of the present invention is to provide a semiconductor package reducing the influence due to thermal stress and therefore resistant to breakage and able to improve the reliability and a method of production of the same.

To attain the above object, the present invention provides a semiconductor package provided with a heat radiator reducing the influence due to thermal stress and achieving a further improvement of reliability, wherein the heat radiator is made a heat radiator (13) of a shape comprised of a heat radiation plate plus a box shaped part and wherein this box shaped part encloses the semiconductor chip (12) as a whole together with a board (11) via a metallic bonding material (15).

### BRIEF DESCRIPTION OF THE DRAWINGS

The above object and features of the present invention will be more apparent from the following description of the preferred embodiments given with reference to the accompanying drawings, wherein:

FIGS. 1A and FIG. 1B are cross-sectional views showing first and second basic configurations according to the present invention;

FIG. 2 is a cross-sectional view showing a concrete example of the configuration according to the present invention;

FIG. 3 is a plan view of a heat radiator 13 of FIG. 2 as seen from a board 11 side;

FIG. 4 is a cross-sectional view showing enlarged portions of facing surfaces shown in FIG. 2 and FIG. 3;

FIG. 5 is a cross-sectional view showing a preferred example of the configuration when a semiconductor package 10 is arranged on a mother board 32;

FIG. 6 is a plan view of a ball grid array (BGA) of FIG. 5 as seen from the mother board side;

FIG. 7 is a diagram showing production steps of a structure shown in FIG. 9;

FIG. 8 is a diagram showing production steps of the structure of the present invention;

FIG. 9 is a cross-sectional view showing the structure disclosed in Japanese Patent Publication No. 2002-158316; and

FIG. 10 is a cross-sectional view showing the structure disclosed in Japanese Patent Publication No. 2002-203866.

### DESCRIPTION OF THE PREFERRED EMBODIMENTS

Preferred embodiments of the present invention will be described in detail below while referring to the attached figures.

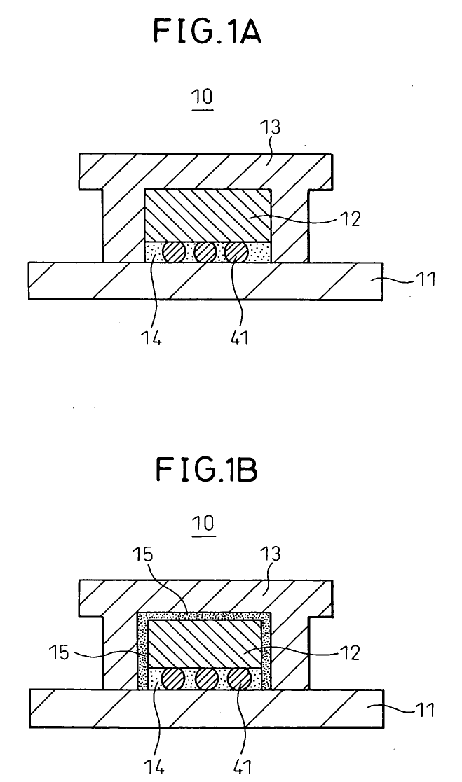

FIG. 1A and FIG. 1B are cross-sectional views showing first and second basic configurations according to the present invention.

Each of the semiconductor packages 10 according to the basic configurations shown in FIGS. 1A and 1B is a semiconductor package provided with a semiconductor chip 12, a board 11 supporting this semiconductor chip 12 at its bottom surface, and a heat radiator 13 provided on a back surface of this semiconductor chip 12. First, according to the basic configuration of FIG. 1A, a semiconductor package comprised of a semiconductor chip 12 enclosed fixed in place with its outer circumference in close contact with a board 11 and a heat radiator 13 is provided.

On the other hand, the semiconductor package 10 of FIG. 1B is comprised of a semiconductor chip 12 with resin filled at its bottom side (underfill 14) and a board 11 and heat radiator 13 between which is sealed a metallic bonding material 15 through which the heat radiator 13 is fixed in close contact to the semiconductor chip 12.

A conventional typical heat radiator is made of a single metallic flat plate. Accordingly, the semiconductor chip 12 and the metallic flat plate only contacted each other two-dimensionally at the back surface of the semiconductor chip 12.

As opposed to this, according to the present invention, as shown in FIGS. 1A and 1B, not only the back surface of the semiconductor chip 12, but also the outer circumference of the semiconductor chip 12 including also its side surfaces are three-dimensionally enclosed by the heat radiator 13. Accordingly, the entire semiconductor chip 12 is completely restrained in its behavior in the heat radiator 13 by the rigid body of the heat radiator 13, so the influence of the thermal stress explained before is suppressed.

As a result, the above breakage becomes hard to occur, and the reliability of the semiconductor package is improved in comparison with the conventional case. This is due to the fact that the thermal stress between the semiconductor chip 12 and the heat radiator 13 is suppressed by the restraint by the rigid body of the heat radiator 13 as described above, but there is still another reason.

Due to the fact that the semiconductor chip 12 is three-dimensionally enclosed by the heat radiator 13, the endothermic effect from the semiconductor chip 12 to the heat radiator 13 rapidly increases and the heat diffusion from the three-dimensionally shaped heat radiator 13 itself to the outside rapidly increases. As a result, the temperature of the semiconductor package 10 itself becomes considerably lower than the conventional temperature, and excessive thermal stress in comparison with the conventional case is no longer generated.

In the end, according to the structure of the present invention shown in FIGS. 1A and 1B, first, tolerance against thermal stress is improved and, second, the heat diffusion efficiency to the outside is improved.

In this way, the heat radiator 13 is fixed in close contact to the semiconductor chip 12 so as to enclose the entire semiconductor chip 12, therefore the outer circumference of the semiconductor chip 12 and the inner circumferential surface of the heat radiator 13 may be directly bonded without the metallic bonding material 15 interposed between them. This is the structure of FIG. 1A.

However, it is actually difficult to make the outer circumference of the semiconductor chip 12 and the inner circumferential surface of the heat radiator 13 completely contact each other with no clearance. If there are scattered sites of clearance, the heat resistances there become extremely large and the heat radiation effect is cancelled.

Therefore, in order not to form such a clearance, preferably the metallic bonding material 15 is interposed between the outer circumference of the semiconductor chip 12 and the inner circumferential surface of the heat radiator 13 as shown in FIG. 1B.

Thus, according to the structure of the present invention shown in FIGS. 1A and 1B, the reliability of the semiconductor package can be improved in comparison with the conventional case.

In order to clarify the effects brought about by the present invention, first, the structures disclosed in the patent publications explained before will be shown.

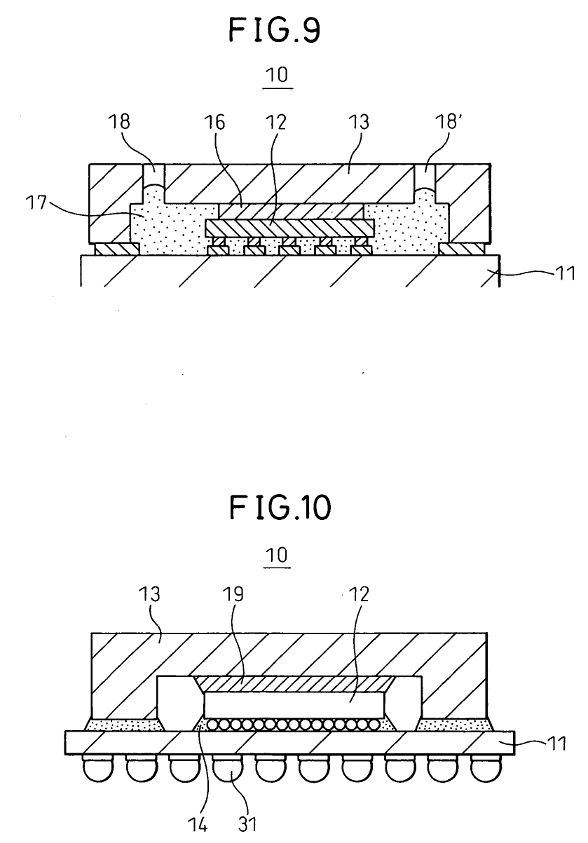

FIG. 9 is a cross-sectional view showing the structure disclosed in Japanese Patent Publication No. 2002-158316, while FIG. 10 is a cross-sectional view showing the structure disclosed in Japanese Patent Publication No. 2002-203866. These structures shown in FIG. 9 and FIG. 10 appear to be similar to the structure of the semiconductor package according to the present invention shown in FIGS. 1A and 1B described above.

Namely, as seen in both figures, semiconductor packages 10 having structures where entire semiconductor chips 12 are enclosed by heat radiators 13 are shown. Note that that same notations are attached to same components throughout all of the diagrams, but in FIG. 9, notations 16, 17, 18, and 18′ are newly attached notations and indicate a heat radiation use sheet 16, a cured resin 17, an injection port 18 of the cured resin 17, and an opening 18′, while in FIG. 10, the notation 19 is newly attached and indicates a heat radiation sheet 19.

These structures according to Japanese Patent Publication No. 2002-158316 and Japanese Patent Publication No. 2002-203866 shown in FIG. 9 and FIG. 10 appear similar to the structure of the present invention shown in FIGS. 1A and 1B, but the structure in Japanese Patent Publication No. 2002-158316 (FIG. 9) is different from the present invention in the point that the heat radiator 13 and the semiconductor chip 12 are not fixed in contact, but a space between the two is filled with a cured resin 17. Further, the structure in Japanese Patent Publication No. 2002-203866 (FIG. 10) is different from the present invention in the point that the heat radiator 13 and the semiconductor chip 12 are not fixed in contact, but a large clearance remains between the two. Accordingly, the object of the present invention cannot be achieved by the structures according to Japanese Patent Publication No. 2002-158316 and Japanese Patent Publication No. 2002-203866.

Below, a concrete example of the configuration will be explained to show the basic structure of the present invention shown in FIGS. 1A and 1B.

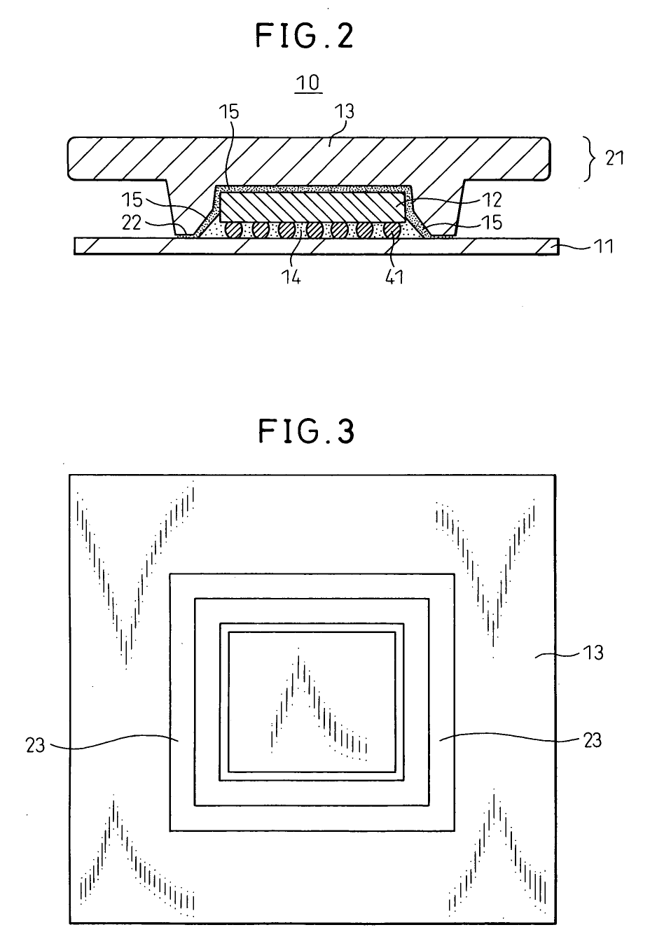

FIG. 2 is a cross-sectional view showing a concrete example of the configuration according to the present invention, while FIG. 3 is a plan view of the heat radiator 13 of FIG. 2 seen from the board 11 side. Note that the description of the semiconductor chip 12 and the configuration of the bottom surface will be omitted.

Referring to FIG. 2 and FIG. 3, the heat radiator 13 has a box shaped part for accommodating the semiconductor chip 12 inside it. The semiconductor chip 12 is enclosed by this box shaped part and the board 11. More preferably, the heat radiator 13 is constituted by the box shaped part and a plate shaped part 21 spreading from the bottom surface of the box shaped part to the outside. As this plate shaped part 21 becomes broader, the cooling performance is improved, but this is made a size of an extent not obstructing the arrangement of the group of adjacent circuit elements placed on the board 11. Such heat radiator 13 is made of a high heat conducting metal such as copper.

As shown in FIG. 2 described above, by fixing the semiconductor chip 12 and the heat radiator 13 in contact while interposing the metallic bonding material 15 between them, the strength of the semiconductor chip 12 itself substantially increases. By this increase of the strength, the reliability of connection between C4 bonded solder parts (bumps) and the board 11 filled with resin by the underfill 14 is improved.

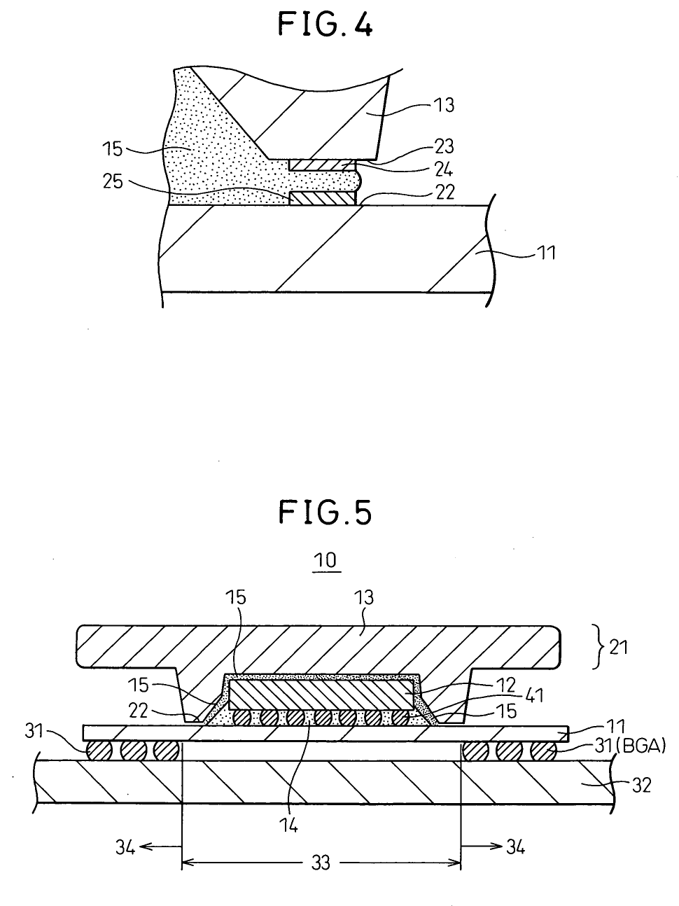

In this case, when the facing surfaces between the above box shaped part and the board 11 (22 of FIG. 2 and 23 of FIG. 3) are further bonded by the metallic bonding material 15, the rigidity of the semiconductor package 10 further increases and the reliability is further improved. At the bonding of these facing surfaces (22, 23), preferably metallic pads are previously formed. FIG. 4 is an enlarged cross-sectional view showing facing surface (22, 23) portions shown in FIG. 2 and FIG. 3. The metallic pads are shown as notations 24 and 25.

Here, as shown in FIG. 2, when studying the metallic bonding material 15 filled around the outer circumference of the semiconductor chip 12 over a range from the back surface of the semiconductor chip 12 to the above facing surface 23, (i) this metallic bonding material 15 is desirably made of an alloy including tin and lead, preferably solder, but (ii) this metallic bonding material 15 may be made by a resin material containing high heat conducting fine metallic grains. As these high heat conducting fine metallic grains, use can be made of silver, copper, or aluminum. Alternatively, as a substitute thereof, it is also possible to use alumina.

The semiconductor package 10 explained above is arranged on a mother board to be assembled as a component in an electronic apparatus. The structure in this case will be explained with reference to the drawings.

FIG. 5 is a cross-sectional view showing a preferred example of the configuration when a semiconductor package of the present invention is arranged on a mother board. Namely, as a preferred example of the configuration when a semiconductor package 10 is placed on a top surface of a mother board 32 via a ball grid array (BGA) made of a plurality of solder balls 31, solder balls 31 are formed on the lower surface of the board 11 other than a region 33 of that lower surface facing the semiconductor package 10, that is, only in a region 34.

When describing the above preferred example of the configuration according to FIG. 2 and FIG. 3, when the heat radiator 13 is configured to have a box shaped part accommodating the semiconductor chip 12 inside this and enclose the semiconductor chip 12 by this box shaped part and the board 11, preferably the above solder balls 31 are formed outside a circumferential edge portion (facing surface 22 of FIG. 2) on the opening side of that box shaped part.

In this way, the BGA is formed avoiding the region 33 in FIG. 5 and in only the region 34 for the following reason. Note that this is true also for a case of a land grid array (LGA) although the reason will be explained by taking a BGA as an example.

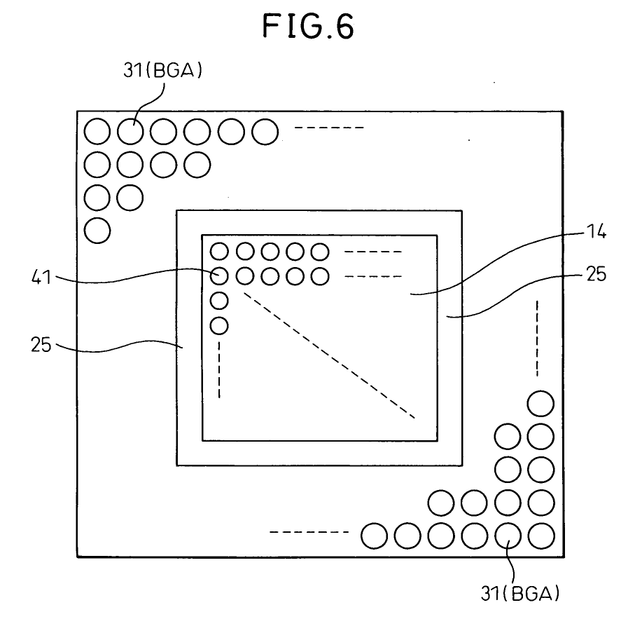

Referring to for example FIG. 10 explained before, the BGA constituted by the group of solder balls 31 drawn at a lower end in the figure becomes different in reliability between a region where a structure (10 of FIG. 10) or stiffener exists above the BGA via the board 11 and a region where there is no such thing. Usually, there is a difference in elongation/shrinkage of the board due to for example temperature fluctuation according to whether or not there is any structure above the BGA. That difference exerts an influence upon the reliability when seen as the overall BGA. Then, it is more advisable if the BGA is not formed in the region 33 where the semiconductor package 10 shown in FIG. 5 exists, but the BGA is formed in only the region 34 other than the former to prevent the drop in the reliability of BGA. The BGA constituted in this way becomes as shown in FIG. 6.

FIG. 6 is a plan view of the BGA of FIG. 5 as seen from the mother board side. Note, this is drawn so that the semiconductor chip 12 etc. on the board 11 appear transparent. Those seen as if they were transparent are a metal (Au) pad 25 shown in FIG. 4, bumps 41 on the bottom surface side of the semiconductor chip, and the underfill 14.

As shown in FIG. 6, the group of the solder balls 31 forming the BGA is formed other than at the portion inside from the metal pad 25, i.e., on only outside from that.

The semiconductor package 10 according to the present invention explained above has an advantage in the method of production as well. The method of production of the semiconductor package 10 according to this present invention is basically comprised of the following first process, second process, and third process:

First process: Filling resin (underfill 14) between bumps 41 for bonding the bottom surface of the semiconductor chip 12 and the board 11;

Second process: Placing the metallic bonding material 15 on the back surface of that resin filled semiconductor chip 12; and

Third process: Lowering the heat radiator 13 having such a box shaped part for accommodating the semiconductor chip 12 inside the same from above the metallic bonding material 15 placed on the back surface and pressing the heat radiator 13 toward the semiconductor chip 12 so that the metallic bonding material 15 completely fills the clearance between the semiconductor chip 12 and the heat radiator 13. Note that, the above-described third process is carried out in a heated state particularly when using solder.

When taking note of the above-described third process here, a first bonding step between the inner surface of the heat radiator 13 and the back surface of the semiconductor chip 12 and a second bonding step between an open end (23) of this heat radiator 13 and the board 11 are completed at one time in that third process. This is an advantage not existing in the conventional production of a semiconductor package. For example, this is apparent when compared with the method of production of the semiconductor package shown in FIG. 9.

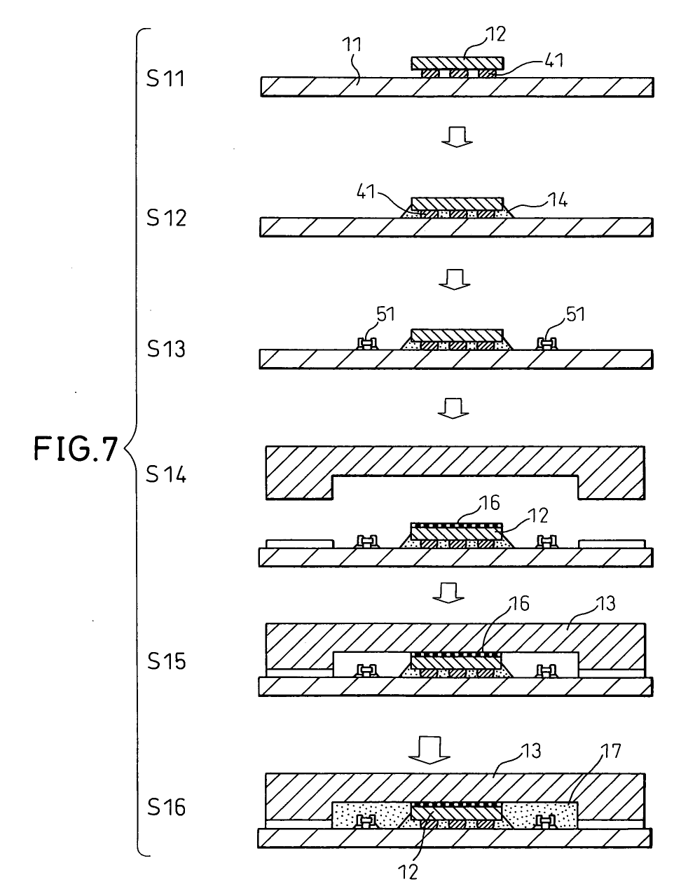

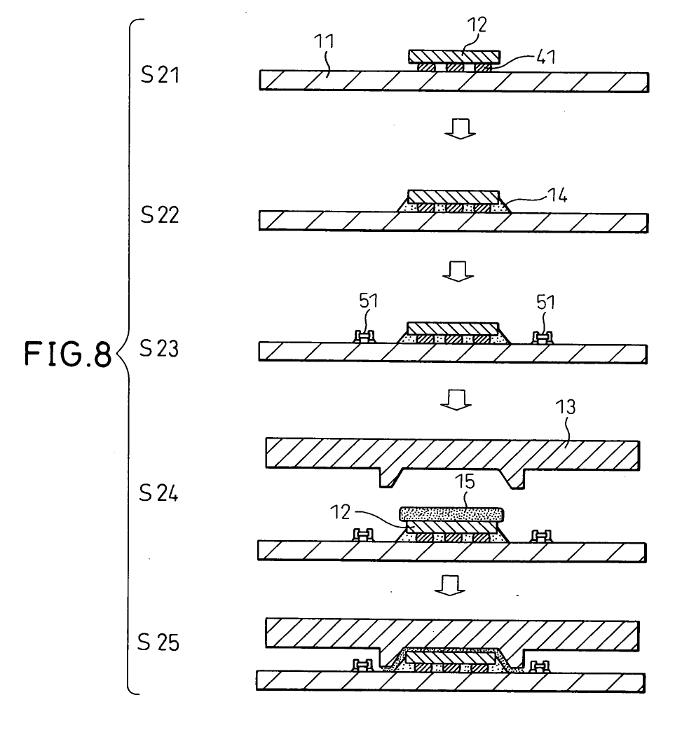

FIG. 7 is a diagram showing the production steps of the structure shown in FIG. 9, and FIG. 8 is a diagram showing production steps of the structure according to the present invention.

Referring to FIG. 7 first,

Step S11

The semiconductor chip 12 is mounted on the board 11 by the bumps 41.

Step S12

The resin is filled between bumps 41 to form the underfill 14.

Step S13

The other chip part 51 to be arranged on the periphery of the semiconductor package 10 is mounted.

Step S14

The heat radiation sheet 16 is placed on the back surface of the semiconductor chip 12, then the heat radiator 13 is moved downward.

Step S15

The heat radiator 13 is pressed against the back surface of the semiconductor chip 12 via the heat radiation sheet 16.

Step S16

The space formed between the heat radiator 13 and the semiconductor chip 12 is filled with the cured resin 17.

On the other hand, when referring to FIG. 8 for the production steps in the present invention,

Step S21: Same as S11 in FIG. 7;

Step S22: Same as S12 in FIG. 7;

Step S23: Same as S13 in FIG. 7; and

Step S24: Almost same step as S14 in FIG. 7 although the shape of the heat radiator 13 and the used bonding material 15 are different from those in FIG. 7.

Thereafter, the production steps of the present invention are completed by step S25. However, in FIG. 7, the semiconductor package covered is completed after passing through the two steps of steps S15 and S16 explained before. That is, in the present invention, the two steps of steps S15 and S16 of FIG. 7 can be finished by one step S25.

As explained above, according to the present invention, a semiconductor package 10 increasing the tolerance against thermal stress and improving the reliability can be realized by using a production process more simplified than the conventional process.

While the invention has been described with reference to specific embodiments chosen for purpose of illustration, it should be apparent that numerous modifications could be made thereto by those skilled in the art without departing from the basic concept and scope of the invention.

What is claimed is:

1. A semiconductor package provided with a semiconductor chip, a board for supporting the semiconductor chip at its bottom surface, and a heat radiator provided on a back surface of the semiconductor chip, wherein
an outer circumference of said semiconductor chip is enclosed by said heat radiator so that said semiconductor chip is fixed in contact with said board and said heat radiator.

2. A semiconductor package as set forth in claim 1, wherein a metallic bonding material sealed between the outer circumference of said semiconductor chip having said bottom surface side filled with a resin and said board and heat radiator is used to fix the heat radiator in contact with the semiconductor chip.

3. A semiconductor package as set forth in claim 2, wherein said heat radiator has a box shaped part for accommodating said semiconductor chip inside that and said box shaped part and board enclose the semiconductor chip.

4. A semiconductor package as set forth in claim 3, wherein said heat radiator is constituted by said box shaped part and a plate shaped part extending from the bottom surface of the box shaped part toward the outside thereof.

5. A semiconductor package as set forth in claim 3, wherein the facing surfaces between said box shaped part and said board are bonded by said metallic bonding material.

6. A semiconductor package as set forth in claim 2, wherein said heat radiator is made of a high heat conducting metal.

7. A semiconductor package as set forth in claim 2, wherein said metallic bonding material is made of an alloy including tin and lead.

8. A semiconductor package as set forth in claim 2, wherein said metallic bonding material is made of a resin material containing high heat conducting fine metal grains.

9. A semiconductor package as set forth in claim 8, wherein said heat conducting fine metal grains are made of silver, copper, or aluminum.

10. A semiconductor package as set forth in claim 2, wherein when said semiconductor package is placed on a top surface of a mother board via a ball grid array formed by a plurality of solder balls, said plurality of solder balls are formed on a lower surface of said board except a region of the lower surface facing the semiconductor package.

11. A semiconductor package as set forth in claim 10, wherein said heat radiator has a box shaped part for accommodating said semiconductor chip inside that, and, when the semiconductor chip is enclosed by the box shaped part and said board, said plurality of solder balls are formed on the outside from a circumferential edge region on an opening side of the box shaped part.

12. A printed circuit board on which the semiconductor package disclosed in claim 1 is mounted.

13. An electronic apparatus having a built-in printed circuit board disclosed in claim 12.

14. A method of production of a semiconductor package provided with a semiconductor chip, a board for supporting the semiconductor chip at its bottom surface, and a heat radiator provided on the back surface side of the semiconductor chip, comprising:
a first step of filling a resin between bumps for bonding the bottom surface of said semiconductor chip and said board;
a second step of placing a metallic bonding material on the back surface of said resin filled semiconductor chip; and
a third step of lowering said heat radiator having a box shaped part that accommodates said semiconductor chip inside it from above said metallic bonding material placed on said back surface and pressing the heat radiator toward the semiconductor chip so that the metallic bonding material completely buries the clearance between said semiconductor chip and said heat radiator.

15. A method of production of the semiconductor package as set forth in claim 14, wherein said third step is carried out in a heated state.
